(19) United States
(12) Patent Application Publication
(10) Pub. No.: US 2020/0049329 A1
(43) Pub. Date: Feb. 13, 2020

(54) LED STRIP THAT CAN BE BENT IN THREE-DIMENSIONAL SPACE

(71) Applicant: General lighting Electronic Co.,Ltd, Dongguan (CN)

(72) Inventor: Zhiliang He, Dongguan (CN)

(73) Assignee: General lighting Electronic Co.,Ltd, Dongguan (CN)

(21) Appl. No.: 16/238,798

(22) Filed: Jan. 3, 2019

(30) Foreign Application Priority Data
Aug. 8, 2018 (CN) 201821277990.3

(51) Int. Cl. F21V 19/00; H05K 1/02

(52) U.S. Cl. CPC F21V 19/001; F21Y 2115/10; H05K 2201/10106; H05K 1/028

(57) ABSTRACT

An LED strip that can be bent in three-dimensional space of the invention includes a printed circuit board, and at least one hole is opened in the printed circuit board. The opening of the holes does not affect the conductivity of the printed circuit board but reduces the mechanical stress of the printed circuit board, thereby the printed circuit board or the LED strip can be bent in three-dimensional space without being destroyed. The installation problem in three-dimensional spaces is solved, in other words, the difficulty of the installation of the LED strip is decreased, so that, a space design with the LED strips can be made better, the performance of the LED strips is improved, and the application field of the LED strips is expanded.

### RELATED APPLICATIONS

This application claims the benefit of Chinese patent application No 201821277990.3, filed Aug. 8, 2018, with a title of “LED STRIP THAT CAN BE BENT IN THREE-DIMENSIONAL SPACE”, which is incorporated herein by reference in its entirety.

### FIELD OF THE INVENTION

The invention relates to an LED strip, more particularly, to an LED strip that can be bent in three-dimensional space.

### BACKGROUND OF THE INVENTION

Flexible LED strips are characterized by high brightness, long ice life, good energy saving, being environment-friendly, etc., thereby they are widely used in decoration and lighting markets, such as signboard, billboard, building outline, indoor ceiling lighting, automobile body decoration and so on. The flexible LED strip generally consists of a core wire, a flexible strip-shaped circuit board and a coating layer, and LED SMD lamp beads are configured on the flexible strip-shaped circuit board.

At present, the LED strips on the market can only be bent in two-dimensional space, and can not be bent in three-dimensional space. Therefore, the LED strips can only be applied to plane objects, and can not be conveniently applied to three-dimensional changing spaces. Otherwise, the LED strips may be damaged and can not be normally used during the installation process.

### SUMMARY OF THE INVENTION

One objective of the present invention is to provide an LED strip that can be bent in three-dimensional space, satisfying the installation problem in three-dimensional spaces.

The above objective is achieved by providing an LED strip that can be bent in three-dimensional space, which includes a printed circuit board, and at least one hole is opened in the printed circuit board.

Preferably, the hole is in the shape of a waist or an oval. Regular holes make the printed circuit board gets torsion evenly and not easy broken.

Preferably, the LED strip that can be bent in three-dimensional space further includes several LED lamp beads, the holes are spaced apart by the LED lamp beads, and at least one LED lamp bead is arranged between two adjacent holes.

Preferably, the holes are evenly spaced on the printed circuit board.

Preferably, the LED strip that can be bent in three-dimensional space further includes a transparent covering layer, the printed circuit board and the LED lamp beads are configured in the covering layer.

Preferably, the LED lamp beads are configured on one side of the printed circuit board.

In comparison with the prior art, the LED strip that can be bent in three-dimensional space of the invention includes a printed circuit board, and at least one hole is opened in the printed circuit board. The opening of the holes does not affect the conductivity of the printed circuit board but reduces the mechanical stress of the printed circuit board, thereby the printed circuit board or the LED strip can be bent in three-dimensional space without being destroyed. The installation problem in three-dimensional spaces is solved, in other words, the difficulty of the installation of the LED strip is decreased, so that, a space design with the LED strips can be made better, the performance of the LED strips is improved, and the application field of the LED strips is expanded.

### BRIEF DESCRIPTION OF THE DRAWINGS

The accompanying drawings facilitate an understanding of the various embodiments of this invention. In such drawings:

FIG. 1 is a schematic view of an LED strip that can be bent in three-dimensional space;

FIG. 2 is another schematic view of an LED strip that can be bent in three-dimensional space, showing the LED strip has been bent.

### DETAILED DESCRIPTION OF ILLUSTRATED EMBODIMENTS

Various preferred embodiments of the invention will now be described with reference to the figures for detailed description of technical content and structural features of the invention.

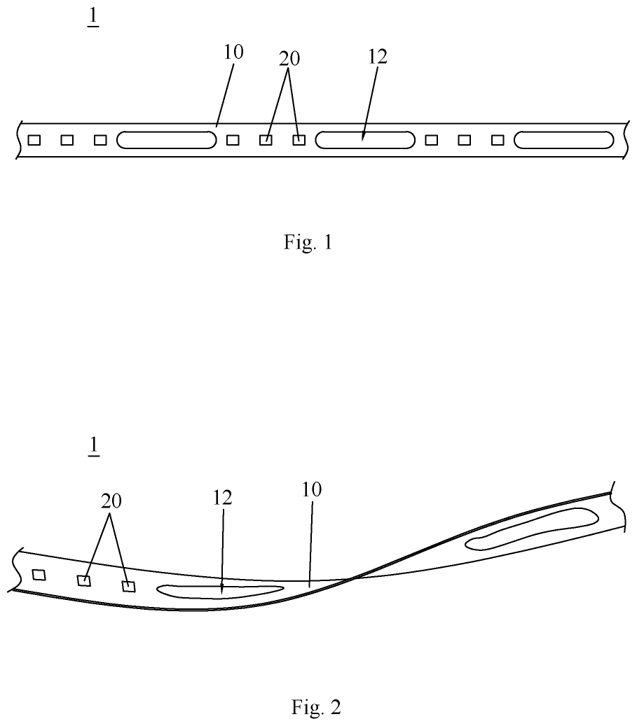

An LED strip that can be bent in three-dimensional space 1 is provided, which can solve the installation problem in three-dimensional spaces. Referring to FIG. 1 to FIG. 2, the LED strip that can be bent in three-dimensional space 1 includes a printed circuit board 10 and several LED lamp beads 20, and at least one hole 12 is opened in the printed circuit board 10. The hole 12 is in the shape of a waist or an oval, the printed circuit board 10 having regular holes 12 gets torsion evenly and can not be easily broken. The holes 12 are spaced apart by the LED lamp beads 20, and at least one LED lamp bead 20 is arranged between two adjacent holes 12. In this embodiment, several holes 12 are in the shape of a waist and evenly opened in the printed circuit board 10, three LED lamp beads 20 are arranged between two adjacent holes 12, and the LED lamp beads 20 are configured on one side of the printed circuit board 10. However, the shape, number and size of the holes 12 and the layout of the LED lamp bead 20 are not limited but can be changed according to actual production requirements and consumer demands in other embodiment, so will not repeated here.

Preferably, the LED strip that can be bent in three-dimensional space 1 further includes a transparent covering layer (not shown), the printed circuit board 10 and the LED lamp beads 20 are configured in the covering layer.

In comparison with the prior art, the LED strip that can be bent in three-dimensional space 1 of the invention includes a printed circuit board 10, and at least one hole 12 is opened in the printed circuit board 10. The opening of the holes 12 does not affect the conductivity of the printed circuit board 10 but reduces the mechanical stress of the printed circuit board 10, thereby the printed circuit board 10 or the LED strip 1 can be bent in three-dimensional space without being destroyed. The installation problem in three-dimensional spaces is solved, in other words, the difficulty of the installation of the LED strip 1 is decreased, so that, a space design with the LED strips 1 can be made better, the performance of the LED strips 1 is improved, and the application field of the LED strips 1 is expanded.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. An LED strip that can be bent in three-dimensional space, comprising a printed circuit board, and at least one hole being opened in the printed circuit board, wherein the at least one hole reduces the mechanical stress of the printed circuit board, thereby the printed circuit board can be bent in three-dimensional space.

2. The LED strip that can be bent in three-dimensional space according to claim 1, wherein the hole is in the shape of a waist or an oval.

3. The LED strip that can be bent in three-dimensional space according to claim 1, further comprising several LED lamp beads, the holes being spaced apart by the LED lamp beads, and at least one LED lamp bead being arranged between two adjacent holes.

4. The LED strip that can be bent in three-dimensional space according to claim 1, wherein the holes are evenly spaced on the printed circuit board.

5. The LED strip that can be bent in three-dimensional space according to claim 3, further comprising a transparent covering layer, the printed circuit board and the LED lamp beads being configured in the covering layer.

6. The LED strip that can be bent in three-dimensional space according to claim 3, wherein the LED lamp beads are configured on one side of the printed circuit board.
